(19) United States
(12) Patent Application Publication
(10) Pub. No.: US 2024/0284695 A1
(43) Pub. Date: Aug. 22, 2024

(54) QUANTUM DOT LIGHT-EMITTING DEVICE, MANUFACTURING METHOD THEREFOR, AND DISPLAY APPARATUS

(71) Applicant: TCL Technology Group Corporation, Huizhou, Guangdong (CN)

(72) Inventor: Kaimin CHEN, Huizhou, Guangdong (CN)

(73) Assignee: TCL Technology Group Corporation, Huizhou, Guangdong (CN)

(21) Appl. No.: 18/570,100

(22) PCT Filed: Sep. 13, 2022
(86) PCT No.: PCT/CN2022/118448

§ 371 Date: Dec. 14, 2023

(30) Foreign Application Priority Data
Sep. 16, 2021 (CN) 202111086665.5

(51) Int. Cl. H10K 50/115; H10K 50/13; H10K 50/15; H10K 50/16; H10K 50/81; H10K 50/82; H10K 85/10

(52) U.S. Cl. CPC H10K 50/115; H10K 50/13; H10K 50/15; H10K 50/16; H10K 50/81; H10K 50/82; H10K 85/1135; H10K 85/151

(57) ABSTRACT

Disclosed is a quantum dot light-emitting device, a manufacturing method thereof, and a display apparatus. There are at least two light-emitting layers, each of the light-emitting layers includes a core-shell quantum dot, the core-shell quantum dot includes a core and at least one shell layer coated on a surface of the core, thicknesses of respective outermost shell layers of the core-shell quantum dots of the quantum dot light-emitting layers become sequentially increased in a direction from an anode to a cathode.

The present disclosure claims priority to Chinese Patent Application No. 202111086665.5, filed in the China National Intellectual Property Administration on Sep. 16, 2021 and entitled “QUANTUM DOT LIGHT-EMITTING DEVICE AND DISPLAY APPARATUS”, the content of which is incorporated herein by reference in its entirety.

### TECHNICAL FIELD

The present disclosure relates to the field of light-emitting devices, and in particular, to a quantum dot light-emitting device, a manufacturing method thereof, and a display apparatus.

### BACKGROUND

Colloidal quantum dots (CQDs) have proven to be excellent semiconductor materials for photovoltaic devices and applications, such as quantum dot light-emitting diodes (QLED), photodetectors, and photovoltaics, because of their tunable band gap by quantum size effects. CQD, in combination with solution handling capabilities thereof, can become a primary candidate material for an ink jet printer (IJP) used for manufacturing the next generation QLED display. In the display industry, IJP has proven to be able to address the problems associated with large-area fabrication of fine metal masks, potentially reducing manufacturing costs, thus attracting great interest and investment in academia and industry.

At present, with the improvement of materials and the optimization of device structure, the maximum current efficiency and the device lifetime of the quantum dot light-emitting diode are greatly improved, the maximum current efficiency of the red and green quantum dot devices is close to 100%, and the device lifetime of the red quantum dot devices is close to the commercial standard. One of the key indicators that needs to be improved for the commercialization of QLED is the efficiency of the device under a general use luminance. The existing QLED can achieve the maximum current efficiency basically in compliance with the standard, but has a poor efficiency under the general use luminance, often with only half or even less of the maximum efficiency, while there are few solutions to this problem.

### Technical Problem

There is a need to solve the problem of poor efficiency of the existing quantum dot light-emitting devices under a general use luminance (e.g., in a range of 300-1000 cd/m² luminance).

### Technical Solutions

Accordingly, the present disclosure provides a quantum dot light-emitting device and a method of manufacturing the same, and a display apparatus.

An embodiment of the present disclosure provides a quantum dot light-emitting device including an anode, a cathode, and a light-emitting layer disposed between the anode and the cathode, wherein the light-emitting layer includes a first quantum dot light-emitting layer to an Nth quantum dot light-emitting layer sequentially arranged in a direction from the anode to the cathode, N is an integer greater than or equal to 2, the first quantum dot light-emitting layer includes a first core-shell quantum dot, the Nth quantum dot light-emitting layer includes an Nth core-shell quantum dot, each core-shell quantum dot includes a core and at least one shell layer coated on a surface of the core, and thicknesses of respective outermost shell layers of the first core-shell quantum dot to the Nth core-shell quantum dot become sequentially increased.

Optionally, in some embodiments of the present disclosure, one or more of the first core-shell quantum dot to the Nth core-shell quantum dot are of a multi-shell layer structure, respectively, and an energy level width of an outermost shell layer of the multi-shell layer structure is greater than an energy level width of the core.

Optionally, in some embodiments of the present disclosure, the light-emitting layer is composed of the first quantum dot light-emitting layer and a second quantum dot light-emitting layer, the first quantum dot light-emitting layer includes the first core-shell quantum dot, the second quantum dot light-emitting layer includes a second core-shell quantum dot, a thickness of an outermost shell layer of the second core-shell quantum dot is greater than that of the first core-shell quantum dot, and energy level widths of the outermost shell layers of the first core-shell quantum dot and the second core-shell quantum dot are greater than an energy level width of the core, respectively.

Optionally, in some embodiments of the present disclosure, the light-emitting layer is composed of the first quantum dot light-emitting layer, a second quantum dot light-emitting layer, and a third quantum dot light-emitting layer, the first quantum dot light-emitting layer includes the first core-shell quantum dot, the second quantum dot light-emitting layer includes a second core-shell quantum dot, the third quantum dot light-emitting layer includes a third core-shell quantum dot, thicknesses of respective outermost shell layers of the first core-shell quantum dot to the third core-shell quantum dot become sequentially increased, and energy level widths of the outermost shell layers of the first core-shell quantum dot, the second core-shell quantum dot, and the third core-shell quantum dot are greater than an energy level width of the core, respectively.

Optionally, in some embodiments of the present disclosure, the first core-shell quantum dot to the Nth core-shell quantum dot are a type I quantum dot.

Optionally, in some embodiments of the present disclosure, emission peak wavelengths of any two of the first quantum dot light-emitting layer to the Nth quantum dot light-emitting layer are same as each other, or an absolute value of a difference between emission peak wavelengths of any two of the first quantum dot light-emitting layer to the Nth quantum dot light-emitting layer is less than 1 nm.

Optionally, in some embodiments of the present disclosure, one or more of the first core-shell quantum dot to the Nth core-shell quantum dot have two shell layers, three shell layers, or four shell layers, respectively.

Optionally, in some embodiments of the present disclosure, energy level widths of corresponding shell layers of one or more of the first core-shell quantum dot to the Nth core-shell quantum dot become sequentially widened from a center of the core-shell quantum dots outward.

Optionally, in some embodiments of the present disclosure, shell layers, except for the outermost shell layers, of the first core-shell quantum dot to the Nth core-shell quantum dot have a same thickness distribution.

Optionally, in some embodiments of the present disclosure, the quantum dot light-emitting device is a blue quantum dot light-emitting device or a green quantum dot light-emitting device, the first core-shell quantum dot to the Nth core-shell quantum dot each independently have three or four shell layers, the thicknesses of the respective outermost shell layers of the first core-shell quantum dot to the Nth core-shell quantum dot become sequentially increased, and thicknesses of respective secondary outer shell layers of the first core-shell quantum dot to the Nth core-shell quantum dot become sequentially increased.

Optionally, in some embodiments of the present disclosure, the quantum dot light-emitting device is a red quantum dot light-emitting device, the first core-shell quantum dot to the Nth core-shell quantum dot each independently have three or four shell layers, and thicknesses of all of the shell layers of each of the first core-shell quantum dot to the Nth core-shell quantum dot become sequentially increased.

Optionally, in some embodiments of the present disclosure, cores of the first core-shell quantum dot to the Nth core-shell quantum dot are each independently selected from one or more of CdSe, CdS, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, CdZnSTe, CdSeSTe, ZnSeSTe, CdZnSeSTe, InP, InAs, InAsP, PbS, PbSe, PbTe, PbSeS, PbSeTe, or PbSTe; and the shell layers of the first core-shell quantum dot to the Nth core-shell quantum dot are each independently selected from one or more of CdSe, CdS, ZnSc, ZnS, CdTe, ZnTe, CdZnS, CdZnSe, CdZnTe, ZnScS, ZnSeTe, ZnTeS, CdSeS, CdSeTe, CdTeS, CdZnScS, CdZnSeTe, CdZnSTe, CdSeSTe, ZnSeSTe, CdZnScSTe, InP, InAs, InAsP, PbS, PbSe, PbTe, PbSeS, PbSeTe, or PbSTe.

Optionally, in some embodiments of the present disclosure, one or more of the first core-shell quantum dot to the Nth core-shell quantum dot are one of a CdSe//ZnSe//ZnS quantum dot, a CdSe//CdZnSe//CdZnS quantum dot, or a InP//GaP//ZnS quantum dot.

Optionally, in some embodiments of the present disclosure, the quantum dot light-emitting device further includes a hole transport layer disposed between the light-emitting layer and the anode, and an electron transport layer disposed between the light-emitting layer and the cathode, preferably, the quantum dot light-emitting device further includes a hole injection layer disposed between the anode and the hole transport layer.

Optionally, in some embodiments of the present disclosure, a valence band energy level of the hole injection layer is higher than that of the hole transport layer, the valence band energy level of the hole transport layer is higher than that of the outermost shell layer of the first core-shell quantum dot in the adjacent first quantum dot light-emitting layer, and a valence band energy level of the electron transport layer is lower than that of the outermost shell layer of the Nth core-shell quantum dot in the adjacent Nth quantum dot light-emitting layer; a conduction band energy level of the hole injection layer is lower than that of the hole transport layer, the conduction band energy level of the hole transport layer is higher than that of the outermost shell layer of the first core-shell quantum dot in the adjacent first quantum dot light-emitting layer, and a conduction band energy level of the electron transport layer is lower than that of the outermost shell layer of the Nth core-shell quantum dot in the adjacent Nth quantum dot light-emitting layer.

Optionally, in some embodiments of the present disclosure, a material of the hole transport layer is selected from one or more of poly(9,9-dioctylfluorene-co-N-(4-butylphenyl)diphenylamine), poly(3-hexylthiophene), poly(9-vinylcarbazole), poly[bis(4-phenyl)(4-butylphenyl)amine], 4,4′,4′-tris(carbazol-9-yl)triphenylamine, 4,4′-bis(9-carbazol)biphenyl; a material of the electron transport layer is selected from a N-type nano-metal oxide, and the N-type nano-metal oxide is selected from one or more of zinc oxide, titanium dioxide, magnesium oxide, aluminum oxide, or oxides of alloys of the metals; a material of the hole injection layer is selected from one or more of poly(3,4-ethylenedioxythiophene)-poly(styrene sulfonate), 4,4′,4″-tris(N-3-methylphenyl-N-phenylamino)triphenylamine, 4,4′,4″-tris[2-naphthylphenylamino]triphenylamine, 2,3,6,7,10,11-hexacyano-1,4,5,8,9,12-hexaazatriphenylene, 2,3,5,6-tetrafluoro-7,7′,8,8′-tetracyanodimethyl-p-benzoquinone, molybdenum trioxide; a material of the anode is selected from ITO or FTO, and a material of the cathode is selected from one or more of aluminum, magnesium, calcium, silver or alloys thereof.

Accordingly, an embodiment of the present disclosure further provides a display apparatus including the above quantum dot light-emitting device.

Accordingly, an embodiment of the present disclosure further provide a method of manufacturing a quantum dot light-emitting device, including: S1 providing a cathode or an anode; S2, preparing a light-emitting layer on the cathode or the anode, wherein the light-emitting layer includes at least two quantum dot light-emitting layers, each of the quantum dot light-emitting layers includes a core-shell quantum dot, the core-shell quantum dot includes a core and at least one shell layer coated on a surface of the core, and thicknesses of respective outermost shell layers of the core-shell quantum dots of the quantum dot light-emitting layers become sequentially increased in a direction from the anode to the cathode; and S3, preparing the anode or the cathode on the light-emitting layer.

Optionally, in some embodiments of the present disclosure, a hole transport layer is prepared between the light-emitting layer and the anode, and an electron transport layer is prepared between the light-emitting layer and the cathode.

Optionally, in some embodiments of the present disclosure, a hole injection layer is prepared between the anode and the hole transport layer.

### Beneficial Effect

According to the embodiments of the present disclosure, in one aspect, since the light-emitting layer is designed to be a structure including multiple quantum dot light-emitting layers, the thickness of the quantum dot layers is increased, and the efficiency of the quantum dot light-emitting device is improved under a general use luminance. In another aspect, since the thicknesses of the respective outermost shell layers of the core-shell quantum dots of the quantum dot light-emitting layers become sequentially increased in a direction from the anode to the cathode, and a quantum dot having a thinner outermost shell layer is selected for the quantum dot light-emitting layer adjacent to the hole transport side, holes can directly “tunneling” through the thinner outermost shell layer without transition of energy levels through the shell layers during the transporting process, thereby reducing the hole injection barrier and facilitating hole transporting. Meanwhile, a quantum dot having a thicker outermost shell layer is selected for the quantum dot light-emitting layer adjacent to the electron transport side, thereby increasing the difficulty of electron injection, effectively improving the injection balance of electrons and holes, and prolonging the lifetime of the quantum dot light-emitting device.

### BRIEF DESCRIPTION OF THE DRAWINGS

In order to illustrate the technical solutions in the embodiments of the present disclosure more clearly, accompanying drawings involved in the description of the embodiments will be briefly described below. It will be apparent that the accompanying drawings in the following description are merely some of the embodiments of the present disclosure, and other drawings may be obtained according to these drawings for those skilled in the art without involving any inventive effort.

FIG. 1 is a schematic diagram of a structure of a quantum dot light-emitting device according to a first embodiment of the present disclosure.

FIG. 2 is a schematic diagram of a structure of a quantum dot light-emitting device according to a second embodiment of the present disclosure.

FIG. 3 is a schematic diagram of a structure of a quantum dot light-emitting device according to a third embodiment of the present disclosure.

FIG. 4 is a schematic energy level diagram of a quantum dot light-emitting device according to a third embodiment of the present disclosure.

FIG. 5 is a flowchart of a method of manufacturing a quantum dot light-emitting device according to a first embodiment of the present disclosure.

FIG. 6 is a CE-luminance graph of a quantum dot light-emitting device according to some embodiments of the present disclosure and comparative examples.

### DETAILED DESCRIPTION OF EMBODIMENTS

Embodiments of the present disclosure will be described clearly and fully below in connection with the accompanying drawings in the embodiments of the present disclosure. It will be apparent that the described embodiments are merely a part of the embodiments of the present disclosure, rather than all the embodiments. Based on the embodiments in the present disclosure, all other embodiments obtained by a person skilled in the art without involving any inventive effort are within the scope of the present disclosure.

An embodiment of the present disclosure provides a quantum dot light-emitting device and a display apparatus. Detailed descriptions are given below. It is to be noted that the order in which the following embodiments are described is not intended to define a preferred order of the embodiments. Additionally, in the description herein, the term “comprise” or “include” means “including, but not limited to”. Ranges may present in various embodiments of the present disclosure, and it is to be understood that the description of the ranges is merely for convenience and brevity and should not be construed as a limitation on the scope of the present disclosure. Accordingly, it is to be considered that the description of the ranges has particularly disclosed all possible subranges, as well as any single numerical value within that ranges. For example, it is to be considered that a range from 1 to 6 has particularly disclosed subranges, e.g., from 1 to 3, from 1 to 4, from 1 to 5, from 2 to 4, from 2 to 6, from 3 to 6, or the like, and single numerical values within the range, e.g., 1, 2, 3, 4, 5, or 6, which is applicable for any range. Additionally, whenever a range of values is indicated herein, it is meant to include any recited number (including a fractional or integer) within the indicated range.

In the present disclosure, the term “and/or”, indicating an association relationship of associated objects, means that there may be three relationships. For example, “A and/or B” may represent a case where A is present alone, a case where A and B are present at the same time, and a case where B is present alone, in which A and B may be a singular or plural.

In the present disclosure, the phrase “one or more” refers to one or a plurality of elements, and “more” in the “one or more” refers to two or more. The phrase “one or more”, “at least one”, or a similar expression, refers to any combination of these elements defined by the phrase, including a singular element or any combination of the plurality of elements. For example, “at least one of a, b, or c”, or “at least one of a, b, and c”, may represent: a, b, c, a-b (i.e., a and b), a-c, b-c, or a-b-c, in which a, b, and c may be a single or plural.

An embodiment of the present disclosure provides a quantum dot light-emitting device including an anode, a cathode, and a light-emitting layer disposed between the anode and the cathode. The light-emitting layer includes at least two quantum dot light-emitting layers, and each of the quantum dot light-emitting layers comprises a core-shell quantum dot. The core-shell quantum dot includes a core and at least one shell coated a surface of the core. The thicknesses of respective outermost shell layers of the core-shell quantum dots in the quantum dot light-emitting layers become sequentially increased from a direction from the anode to the cathode.

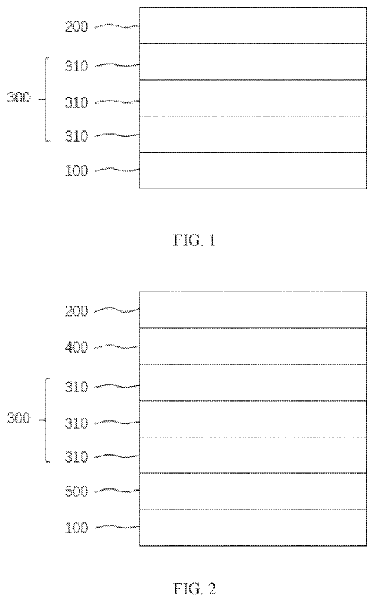

Referring to FIG. 1, a first embodiment of the present disclosure provides a quantum dot light-emitting device including an anode 100, a cathode 200, and a light-emitting layer 300.

The light-emitting layer 300 is provided between the anode 100 and the cathode 200. The light-emitting layer 300 includes a first quantum dot light-emitting layer 310 to an Nth quantum dot light-emitting layer 310 sequentially in a direction from the anode 100 to the cathode 200, and N may be any integer equal to or greater than 2. The first quantum dot light-emitting layer 310 includes a first core-shell quantum dot, and the Nth quantum dot light-emitting layer 310 includes an Nth core-shell quantum dot. Each core-shell quantum dot comprises a core and at least one shell layer coated a surface of the core. The thicknesses of the respective outermost shells of the first core-shell quantum dot to the Nth core-shell quantum dot become sequentially increased.

It is to be understood that in some embodiments, the number of the quantum dot light-emitting layers 310 is two or more, such as two, three, four, or more. The core-shell quantum dots in the respective quantum dot light-emitting layers 310 are the same or different. In an embodiment, N is equal to 3, that is, the light-emitting layer 300 is composed of three quantum dot light-emitting layers 310, as shown in FIG. 1. The first quantum dot light-emitting layer 310 is close to the anode 100, a second quantum dot light-emitting layer 310 is disposed in the middle, and a third quantum dot light-emitting layer 310 is close to the cathode. The first, second, and third quantum dot light-emitting layers 310 include a first core-shell quantum dot, a second core-shell quantum dot, and a third core-shell quantum dot, respectively. Each of the first core-shell quantum dot, the second core-shell quantum dot, and the third core-shell quantum dot includes a core and at least one shell layer coated a surface of the core. The thicknesses of the respective outermost shells of the first core-shell quantum dot, the second core-shell quantum dot, and the third core-shell quantum dot become sequentially increased. That is, the outermost shell of the first core-shell quantum dot has the minimum thickness, and the outermost shell of the third core-shell quantum dot has the maximum thickness.

In the embodiments of the present disclosure, the core-shell quantum dot may be a blue quantum dot, a green quantum dot, or a red quantum dot. The number of shell layers of the core-shell quantum dot may be determined according to the type of selected quantum dots, and the core-shell quantum dot may have a single shell layer or multiple shell layers. The core-shell quantum dot may be a single-shell quantum dot (with one shell) or a multi-shell quantum dot. The number of shell layers of the multi-shell quantum dot is, for example, two, three, four, or more. When the core-shell quantum dot has only one shell layer, the shell layer is the outermost shell layer. When the core-shell quantum dot has two or more shell layers, one of the shell layers farthest from the core is the outermost shell layer. In the embodiments of the present disclosure, the thicknesses of shell layer(s), except for the outermost shell layers, of the respective core-shell quantum dots in the quantum dot light-emitting layers 310 are not limited, and may be the same or different.

In some embodiments, shell layer(s), except for the outermost shell layers, of the respective core-shell quantum dots in the quantum dot light-emitting layers 310 have the same thickness distribution. In some embodiments, the quantum dot-emitting layers 310 have the same type of core-shell quantum dots. For example, in the light-emitting layer 300 composed of three quantum dot light-emitting layers 310, the first core-shell quantum dot, the second core-shell quantum dot, and the third core-shell quantum dot are a CdSe//ZnSe//ZnS blue quantum dot. In the quantum dot light-emitting layers 310, the thicknesses of the respective outermost shell layers of the first core-shell quantum dot, the second core-shell quantum dot, and the third core-shell quantum dot become increased in the direction from the anode 100 to the cathode 200, and the thicknesses of respective secondary outer shell layers of the quantum dot light-emitting layers 310 are equal to each other. Accordingly, the first core-shell quantum dot, the second core-shell quantum dot, and the third core-shell quantum dot may be a CdSe//CdZnSe//CdZnS red quantum dot or an InP//GaP//ZnS green quantum dot.

In other embodiments, shell layer(s), except for the outermost shell layers, of the respective core-shell quantum dots of the quantum dot light-emitting layers 310 have different thickness distributions. For example, the core-shell quantum dot is a blue quantum dot or a green quantum dot, and the quantum dot light-emitting device is correspondingly a blue quantum dot light-emitting device or a green quantum dot light-emitting device. The core-shell quantum dots of the quantum dot light-emitting layers 310 may have three or four shell layers, respectively. For example, each of the first core-shell quantum dot to the Nth core-shell quantum dot has three or four shell layers. In this case, the thickness distributions of the outermost shell layers and the secondary outer shell layers of the core-shell quantum dots of the quantum dot light-emitting layers 310 have a great influence on the hole injection balance, so that the thicknesses of the outermost shell layers and the secondary outer shell layers of the core-shell quantum dots of the quantum dot light-emitting layers become sequentially increased from the direction from the anode 100 to the cathode 200, respectively. Alternatively, the core-shell quantum dot is a red-light quantum dot, and accordingly, the quantum dot light-emitting device is a red-light quantum dot light-emitting device, in which the core-shell quantum dot of each of the quantum dot light-emitting layers 310 may have three or four shell layers. In this case, the thickness distributions of all shell layers of the core-shell quantum dots of the quantum dot light-emitting layers 310 have a great influence on the hole injection balance, so that the thicknesses of all shell layers in the core-shell quantum dots of the quantum dot light-emitting layer 310 become sequentially increased in the direction from the anode 100 to the cathode 200.

As an exemplary embodiment, the light-emitting layer 300 includes a first quantum dot light-emitting layer 310 and a second quantum dot light-emitting layer 310. The first quantum dot light-emitting layer 310 and the second quantum dot light-emitting layer 310 include a first core-shell quantum dot and a second core-shell quantum dot, respectively. The cores of the two core-shell quantum dots are CdZnSe, and the shell layers are CdZnSe//ZnSe//CdZnS//ZnS sequentially from the cores outward. When the particle size of the core-shell quantum dots is compliance with a bluc quantum dot or a green quantum dot, the thickness of the outermost shell ZnS of the second core-shell quantum dot is greater than that of the outermost shell ZnS of the second core-shell quantum dot, and the thickness of the secondary outer shell CdZnS of the second core-shell quantum dot is greater than that of the secondary outer shell CdZnS of the second core-shell quantum dot. That is, the thicknesses of the outermost shells and the secondary outer shells of the quantum dots in the two quantum dot light-emitting layers 310 become increased sequentially in the direction from the anode 100 to the cathode 200, respectively. The thicknesses of other shell layers CdZnSe/ZnSe may be the same or respectively sequentially increased. When the particle size of the core-shell quantum dots is compliance with a red quantum dot, in the two quantum dot light-emitting layers 310, the thicknesses of four shell layers CdZnSe/ZnSc/CdZnS/ZnS become increased sequentially in the direction from the anode 100 to the cathode 200, respectively.

The core-shell quantum dot may further include a ligand. The quantum dot light-emitting layer 310 may include other components as needed, such as a mesoporous material, a semiconductor material with high mobility, and the like, in addition to the core-shell quantum dot. In an embodiment, the quantum dot light-emitting layer 310 contains only the core-shell quantum dot.

The core of the core-shell quantum dot may be selected, for example, from at least one of CdSc, CdS, ZnSe, ZnS, CdTe, ZnTe, CdZnS, CdZnSe, CdZnTe, ZnSeS, ZnSeTe, ZnTeS, CdScS, CdSeTe, CdTeS, CdZnSeS, CdZnSeTe, CdZnSTe, CdSeSTe, ZnSeSTe, CdZnSeSTe, InP, InAs, InAsP, PbS, PbSc, PbTe, PbSeS, PbSeTe, or PbSTe.

The shell layer of the core-shell quantum dot may be selected, for example, from at least one of CdSe, CdS, ZnSc, ZnS, CdTe, ZnTe, CdZnS, CdZnSe, CdZnTe, ZnScS, ZnScTe, ZnTeS, CdScS, CdSeTe, CdTeS, CdZnSeS, CdZnSeTe, CdZnSTe, CdSeSTe, ZnSeSTe, CdZnSeSTe, InP, InAs, InAsP, PbS, PbSe, PbTe, PbSeS, PbSeTe, or PbSTe.

According to the embodiments of the present disclosure, in one aspect, since the light-emitting layer 300 is designed into a structure including multiple quantum dot light-emitting layers 310, the thickness of the quantum dot layers is increased, and the efficiency of the quantum dot light-emitting device under a general use luminance (for example, in a range of 300-1000 cd/m² luminance) is improved. In another aspect, since the thicknesses of the respective outermost shell layers of the core-shell quantum dots of the quantum dot light-emitting layers 310 become sequentially increased in the direction from the anode 100 to the cathode 200, and a quantum dot having a thinner outermost shell layer (compared with an outermost shell layer of the core-shell quantum dot of the quantum dot light-emitting layer 310 adjacent to the electron transport side) is selected for the quantum dot light-emitting layer 310 adjacent to the hole transport side, holes can directly “tunneling” through the outermost shell layer without transition of energy level through the shell layers during the transporting process, thereby reducing the hole injection barrier and facilitating hole transporting. Meanwhile, a quantum dot having a thicker outermost shell layer (compared with an outermost shell layer of the core-shell quantum dot of the quantum dot light-emitting layer 310 adjacent to the hole transport side) is selected for the quantum dot light-emitting layer 310 adjacent to the electron transport side, thereby increasing the difficulty of electron injection, effectively improving the injection balance of electrons and holes, and prolonging the lifetime of the quantum dot light-emitting device.

In some embodiments, in the core-shell quantum dot of each quantum dot light-emitting layer 310, the energy level of each shell layer can completely cover the energy level of the core, thereby forming a type I quantum dot, and in turn binding the generated excitons in the core, which brings a relatively high efficiency and luminance for the light-emitting layer 300. In the embodiments, the energy level of each shell layer can completely cover the energy level of the core, which means that the energy level width of the shell layer can completely cover the energy level width of the core, that is, the energy level width of the core is located within that of the shell layer.

In some embodiments, emission peak wavelengths of any two quantum dot light-emitting layers 310 are the same or substantially the same. The expression of “substantially the same” means that the absolute value of the difference in the emission peak wavelengths of any two quantum dot light-emitting layers 310 is less than 1 nm. Thus, the color emitted by the light-emitting layer 300 is more uniform. In some embodiments, the absolute value of the difference in the full widths at half maximum of any two quantum dot light-emitting layers 310 is less than 1 nm.

In some embodiments, the energy level widths, the valence band energy levels and the conduction band energy levels of the cores of the core-shell quantum dots of any two quantum dot light-emitting layers 310 are the same, respectively. It is to be appreciated that the compositions of the cores of the core-shell quantum dots of any two quantum dot light-emitting layers 310 may be the same or different, provided that the energy level widths, the valence band energy levels, and the conduction band energy levels are the same.

In embodiments of the present disclosure, the thicknesses of any two quantum dot light-emitting layers 310 may be the same or different. In some embodiments, the thickness of any quantum dot light-emitting layer 310 is 10-20 nm. In some embodiments, the quantum dot light-emitting device comprises at least a first quantum dot light-emitting layer 310 and a second quantum dot light-emitting layer, thereby increasing the total thickness of the quantum dot light-emitting layer and improving the luminous efficiency of the quantum dots. In a specific embodiment, the thicknesses of any two quantum dot-emitting layers 310 become sequentially increased in the direction from the anode 100 to the cathode 200. In another embodiment, the thickness of any two quantum dot light-emitting layers 310 is equal to each other.

In embodiments of the present disclosure, the compositions of the core-shell quantum dots of any two quantum dot light-emitting layers 310 may be the same as or different from each other. In an embodiment, the core-shell quantum dots of the respective the quantum dot light-emitting layers 310 have the same composition. It is to be noted that when the core-shell quantum dots are the same, it means that the quantum dots have the same composition, that is, the composition of the cores is the same, and the composition of the shell layers is the same, except for only the different thicknesses of the respective outermost shell layers. For example, the core-shell quantum dot of each quantum dot light-emitting layer 310 is CdSe//ZnSe//ZnS, in which CdSe is the core, ZnSe is the first shell layer, and ZnS is the second shell layer (also the outermost shell layer). The difference between the respective core-shell quantum dots of the quantum dot light-emitting layers 310 is that the thicknesses of the ZnS shell layers are different.

In some embodiments, the core-shell quantum dot of at least one of the first quantum dot light-emitting layer 310 to the Nth quantum dot light-emitting layer 310 is of multiple shell layers, and the energy level widths of the respective shell layers become sequentially widened from the center of the core-shell quantum dots outward. It is to be appreciated that the core-shell quantum dots are generally spherical or spherical-like. The center described herein refers to the center of the core, i.e., the spherical center of the core. The expression of “from the center . . . outward” means outwardly from the spherical center of the core in a radial direction.

It is to be noted that the quantum dot light-emitting device according to the present embodiment may have an upright structure or an inverted structure. In the upright structure, the anode 100 is disposed on the substrate, and in the inverted structure, the cathode 200 is disposed on the substrate. In either the upright structure or the inverted structure, a hole functional layer, such as a hole transport layer, a hole injection layer and/or an electron-blocking layer may be disposed between the anode 100 and the light-emitting layer 300, and an electron functional layer, such as an electron transport layer, an electron injection layer and/or a hole-blocking layer may be further disposed between the cathode 200 and the light-emitting layer 300.

Illustratively, referring to FIG. 2, there is shown a schematic diagram of a structure of a quantum dot light-emitting device according to a second embodiment of the present disclosure, which differs from the first embodiment in that the quantum dot light-emitting device further includes a hole transport layer 500 and an electron transport layer 400. The hole transport layer 500 is provided between the light-emitting layer 300 and the anode 100, and the electron transport layer 400 is provided between the light-emitting layer 300 and the cathode 200.

In an embodiment, the valence band energy level of the hole transport layer is higher than that of the outermost shell layer of the core-shell quantum dot of the adjacent quantum dot light-emitting layer, and the conduction band energy level of the electron transport layer is lower than that of the outermost shell layer of the core-shell quantum dot of the adjacent quantum dot light-emitting layer.

Illustratively, referring to FIG. 3, there is shown a schematic diagram of a structure of a quantum dot light-emitting device according to a second embodiment of the present disclosure, which differs from the second embodiment in that the quantum dot light-emitting device may further include a hole injection layer 600. The hole injection layer 600 is disposed between the anode 100 and the hole transport layer 500.

In an embodiment, the valence band energy level of the hole injection layer is higher than that of the hole transport layer.

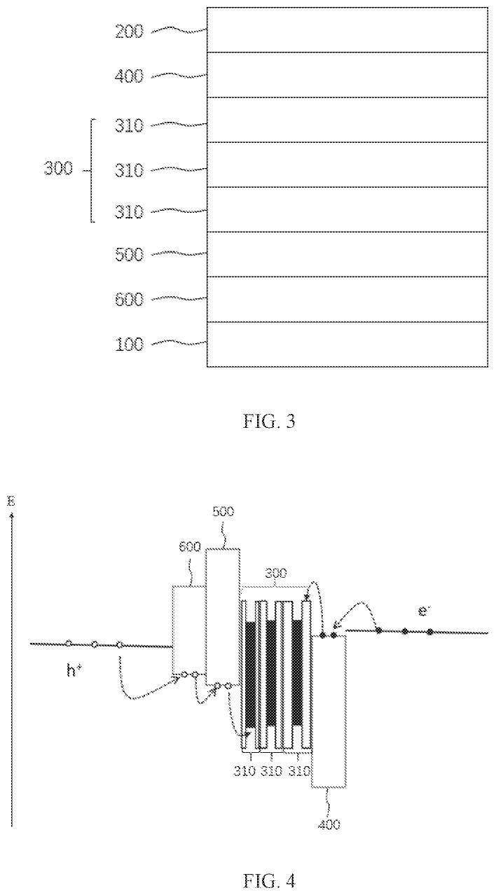

Illustratively, referring to FIG. 4, there is shown a schematic diagram of energy levels, in which the white blocks of the quantum dot light-emitting layers 310 in FIG. 4 represent the energy level positions and thicknesses of the quantum dot shell layers, and the black blocks represent the energy level positions of the quantum dot cores. The valence band energy level of the hole injection layer 600 is higher than that of the hole transport layer 500. The conduction band level of the hole injection layer 600 is lower than that of the hole transport layer 500. The valence band energy level of the hole transport layer 500 is higher than that of the outermost shell layer of the core-shell quantum dot of the adjacent quantum dot light-emitting layer 310. The conduction band level of the hole transport layer 500 is higher than that of the outermost shell layer of the core shell quantum dot of the adjacent quantum dot light-emitting layer 310. The conduction band level of the electron transport layer 400 is lower than that of the outermost shell layer of the core shell quantum dot of the adjacent quantum dot light-emitting layer 310. The valence band energy level of the electron transport layer 400 is lower than that of the outermost shell layer of the core-shell quantum dot of the adjacent quantum dot light-emitting layer 310. Still referring to FIG. 4, holes transition from the hole injection layer 600 to the hole transport layer 500 and tunnels from the hole transport layer 500 through the outermost shell layer of the core-shell quantum dot of the adjacent quantum dot light-emitting layer 310, and electrons transition to the electron transport layer 400 and then transition from the electron transport layer 400 to the outermost shell layer of the core-shell quantum dot of the adjacent quantum dot light-emitting layer 310.

In addition, referring to FIG. 5, an embodiment of the present disclosure further provides a method of manufacturing the above quantum dot light-emitting device, which includes the following steps S1-S3.

At S1, a cathode 200 or an anode 100 is prepared.

At S2, a light-emitting layer 300 is prepared on the cathode 200 or the anode 100. The light-emitting layer 300 comprises at least two quantum dot light-emitting layers 310. Each of the quantum dot light-emitting layers 310 comprises a core-shell quantum dot, and the core-shell quantum dot comprises a core and at least one shell layer coated on the core surface. The thicknesses of the respective outermost shell layers of the core-shell quantum dots of the quantum dot light-emitting layers 310 become sequentially increased in the direction from the anode 100 to the cathode 200.

At S2, the anode 100 or the cathode 200 is prepared on the light-emitting layer 300.

In some embodiments, the method of manufacturing the quantum dot light-emitting device further comprises preparing a hole transport layer 500 and/or an electron transport layer 400.

In some embodiments, the method of manufacturing the quantum dot light-emitting device further comprises preparing a hole injection layer 600.

In various embodiments of the present disclosure, materials of the following functional layers are common materials in the art, taking the following as an example.

A material of the anode 100 is, for example, ITO or FTO.

A material of the cathode 200 may be, for example, an aluminum elemental material, a magnesium elemental material, a calcium elemental material, a silver elemental material, or an alloy material thereof.

A material of the hole transport layer 500 may be, for example, TFB (poly(9,9-dioctylfluorene-co-N-(4-butylphenyl)diphenylamine)), P3HT (poly(3-hexylthiophene)), PVK (poly(9-vinylcarbazole)), poly-TPD (poly[bis(4-phenyl)(4-butylphenyl)amine]), TCTA (4,4′,4′-tris(carbazol-9-yl)triphenylamine), CBP (4,4′-bis(9-carbazol)biphenyl), or the like.

A material of the electron transport layer 400 may be, for example, an N-type nano-metal oxide. The N-type nano-metal oxide may be, for example, at least one of zinc oxide, titanium dioxide, magnesium oxide, aluminum oxide, or oxides of alloys of the above metals.

A material of the hole injection layer 600 may be, for example, PEDOT:PSS (poly(3,4-ethylenedioxythiophene)-poly(styrene sulfonate)), m-MTDATA (4,4′,4″-tris(N-3-methylphenyl-N-phenylamino) triphenylamine), 2-TNATA (4,4′,4″-tris[2-naphthylphenylamino]triphenylamine), HAT-CN (2,3,6,7,10,11-hexacyano-1,4,5,8,9,12-hexaazatriphenylene), F4-TCNQ (2,3,5,6-tetrafluoro-7,7′,8,8′-tetracyanodimethyl-p-benzoquinonc), molybdenum trioxide (MoO₃), or the like.

In various embodiments of the manufacturing method according to the present disclosure, each film layer may be prepared using a chemical method or a physical method. The chemical method includes, but is not limited to, one or more of chemical solution deposition (including sol-gel method and metal-organic deposition), chemical vapor deposition, co-precipitation, and electrochemical deposition. The physical method includes, but is not limited to, one or more of a solution method (such as spin coating, printing, knife coating, dip-and-pull method, soaking, spraying, roll coating, casting, slit coating, or strip coating, or the like), an evaporation method (such as thermal evaporation, electron beam evaporation, magnetron sputtering, or multi-arc ion plating, or the like), and a deposition method (such as physical vapor deposition, atomic layer deposition, pulsed laser deposition, or the like).

The present disclosure further provides a display apparatus including the quantum dot light-emitting device. The display apparatus may include but is not limited to a portable electronic device such as a smartphone, an Internet device, or an electronic book, or may be a display, a liquid crystal television, or the like. Details are not described herein.

The present disclosure will now be described in detail by way of examples.

### Example 1

There is provided a quantum dot light-emitting device having a structure as shown in FIG. 3, which includes an anode 100, a hole injection layer 600, a hole transport layer 500, a light-emitting layer 300, an electron transport layer 400, and a cathode 200 stacked sequentially. The anode 100 is made of ITO. The hole injection layer 600 is made of PEDOT:PSS. The hole transport layer 500 is made of TFB. The electron transport layer 400 is made of ZnO. The cathode 200 is made of Al. The light-emitting layer 300 is composed of three quantum dot light-emitting layers 310 (i.e., the first quantum dot light-emitting layer, the second quantum dot light-emitting layer, and the third quantum dot light-emitting layer sequentially in the direction from the anode 100 to the cathode 200). The quantum dot light-emitting layers 310 are made of a core-shell CdSe//ZnSe//ZnS blue quantum dot, in which CdSe is a core, ZnSe is a first shell layer, and ZnS is a second shell layer. The three quantum dot light-emitting layers 310 have the same emission peak position (the same emission peak wavelength, and the same full width at half maximum).

Each of the three quantum dot light-emitting layers has a thickness of 15 nm. In the core-shell CdSe//ZnSe//ZnS blue quantum dots, the first shell layers ZnSe have a thickness of 6 atomic layers. The difference among the three quantum dot light-emitting layers 310 is only that their outermost shell layers ZnS have different thicknesses. In the direction from the anode 100 to the cathode 200, the thicknesses of the respective outermost shell layers ZnS are 1 atomic layer, 2 atomic layers, and 4 atomic layers sequentially. The thickness of N atomic layers corresponds to the number of layers of shell materials epitaxially grown.

### Example 2

The present embodiment differs from Example 1 in that the quantum dot light-emitting layers 310 are made of a core-shell CdSe//CdZnSe//CdZnS red quantum dot, in which CdSe is a core, CdZnSe is a first shell layer, and CdZnS is a second shell layer. The three quantum dot light-emitting layers 310 have the same emission peak position (the same emission peak wavelength, and the same full width at half maximum).

The three quantum dot light-emitting layers 310 have a thickness of 10 nm, 12 nm, and 15 nm in the direction from the anode 100 to the cathode 200, respectively. The first shell layer CdZnSe has a thickness of 10 atomic layers.

The difference among the three quantum dot light-emitting layers 310 is only that their outermost shell layers CdZnS have different thicknesses. In the direction from the anode 100 to the cathode 200, the thicknesses of the respective outermost shell layers CdZnS are 2 atomic layers, 4 atomic layers, and 6 atomic layers sequentially.

### Example 3

The present embodiment differs from Example 1 in that the light-emitting layer 300 is composed of two quantum dot light-emitting layers 310 (i.e., a first quantum dot light-emitting layer and a second quantum dot light-emitting layer sequentially arranged in the direction from the anode 100 to the cathode 200). The quantum dot light-emitting layers 310 are made of a core-shell InP//GaP//ZnS green quantum dot, in which InP is a core, GaP is a first shell layer, and ZnS is a second shell layer. The two quantum dot light-emitting layers 310 have the same emission peak position (the same emission peak wavelength, and the same full width at half maximum). The two quantum dot light-emitting layers 310 have a thickness of 15 nm and 20 nm in the direction from the anode 100 to the cathode 200, respectively.

The first shell layer GaP has a thickness of 20 atomic layers.

The difference between the two quantum dot light-emitting layers 310 is only that their outermost shell layers ZnS have different thicknesses. In the direction from the anode 100 to the cathode 200, the respective outermost shell layers ZnSe have a thickness of 2 atomic layers and 5 atomic layers sequentially.

### Comparative Example 1

The Comparative Example 1 differs from Example 1 in that the light-emitting layer 300 is composed of one quantum dot light-emitting layer 310, and the outermost shell layer ZnS of the CdSe//ZnSe//ZnS blue quantum dot has a thickness of 2 atomic layers.

The quantum dot light-emitting layer 310 has a thickness of 15 nm. The first shell layer ZnSe has a thickness of 6 atomic layers.

### Comparative Example 2

The Comparative Example 2 differs from Example 1 in that the light-emitting layer 300 is composed of one quantum dot light-emitting layer 310, and the thickness of the quantum dot light-emitting layer 310 is 45 nm, that is, the sum of the thicknesses of the three quantum dot light-emitting layers in Example 1. The first shell layer ZnSe has a thickness of 6 atomic layers and the outermost shell layer ZnS has a thickness of 2 atomic layers.

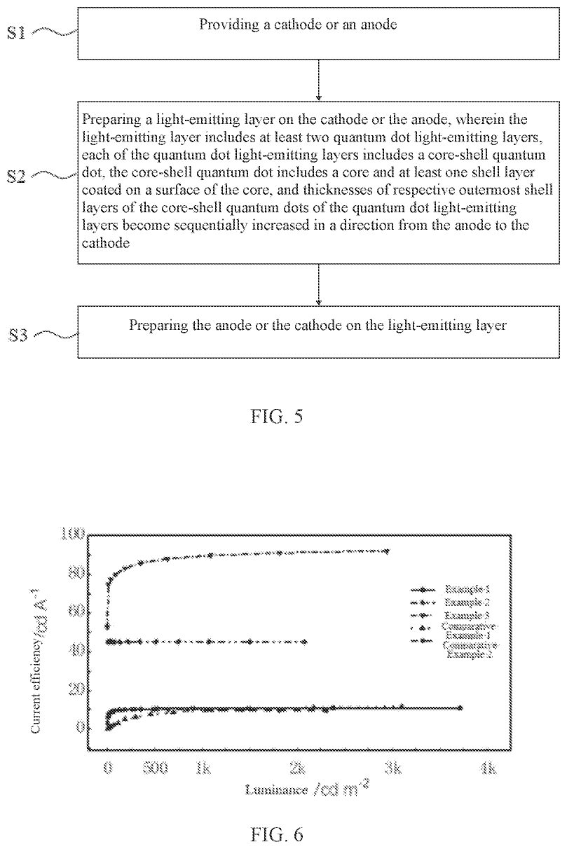

Photoelectric performance test of quantum dot light-emitting devices. The QLED devices prepared in Example 1, Example 2, Example 3, Comparative Example 1, and Comparative Example 2 are respectively tested for the luminous efficiency at the maximum luminance at a current of 2 mA (CE@max), the luminous efficiency at a luminance of 300 cd/m² (CE@300 nit), and the time taken from a luminance of 1000 cd/m² to 95% of the luminance (T95@1 knit), and the results are shown in Table 1. The current efficiency-luminance (CE-luminance) graphs of Example 1, Example 2, Example 3, Comparative Example 1, and Comparative Example 2 are shown in FIG. 6.

TABLE 1

| | Exam- | Exam- | Exam- | Comparative | Comparative |
|---|---|---|---|---|---|
| Performance | ple 1 | ple 2 | ple 3 | Example 1 | Example 2 |
| CE@max | 10.8 | 45 | 92 | 11.6 | 10.2 |
| (cd/A) | | | | | |
| CE@300 nit | 10.2 | 45 | 85 | 6.3 | 10.2 |
| (cd/A) | | | | | |
| T95@1k nit | 108 | 4000 | 2000 | 120 | 10 |
| (hrs) | | | | | |

Note:
nit represents for Nit, and 300 nit = 300 cd/m²

It can be seen from the comparison results of Comparative Example 1 and Comparative Example 2 that, an increase in the thickness of the quantum dot light-emitting layer 310 of QLED can effectively improve the efficiency of the QLED at a general use luminance (300 cd/m²), but significantly reduces the lifetime of the QLED. Reasons for this way may lie in that the increase in the thickness of the quantum dot light-emitting layer 310 of the QLED may cause an imbalance in carrier injection of the device, resulting in a reduction of the lifetime.

Referring to FIG. 6 and Table 1, it can be seen from Example 1, Comparative Example 1, and Comparative Example 2 that, the blue quantum dot light-emitting device of Example 1 of the present disclosure has a luminous efficiency significantly superior to that of Comparative Example 1 at the luminance of 300 cd/m². The luminous efficiency of the device of Example 1 at the luminance of 300 cd/m² is comparable to that of the Comparative Example 2, and the lifetime is significantly better than that of the Comparative Example 2. That is, since the multiple quantum dot light-emitting layers 310 of Example 1 employ core-shell quantum dots whose outer shell layers have a stepwise distribution of thicknesses, the CE@300 nit is improved while the lifetime of the device is well maintained, which significantly alleviates the defect that the lifetime of the device in Comparative Example 2 is poor due to single core-shell distribution at the same total thickness of the quantum dot light-emitting layers. For the blue quantum dot light-emitting device of Example 1, the luminous efficiency of 8.2 cd/A and the T95@1 knit of 108 h also reach a relatively high level in the field of blue quantum dot light-emitting devices. It can also be seen from FIG. 6 that the blue quantum dot light-emitting device of Example 1 exhibits good luminous efficiency over that of Example 1 at a luminance within 500 cd/m².

As can be seen from Examples 2 and 3, the corresponding red and green quantum dot light-emitting devices also have good CE@300 nit and long lifetime. Therefore, the device of the present disclosure can greatly improve the efficiency under the general use luminance while maintaining a good service lifetime due to the structure of the light-emitting layer 300.

The above embodiments of the present disclosure provide a quantum dot light-emitting device, a method for manufacturing the same, and a display apparatus, and describe them in detail. Specific examples are used to describe the principles and implementations of the present disclosure. The description of the above embodiments is merely intended to help understand the technical solutions and the core idea of the present disclosure. It is to be understood by those of ordinary skill in the art that modifications may still be made to the technical solutions described in the foregoing embodiments, or equivalent substitutions may be made to some of the technical features therein. These modifications or substitutions do not depart the essence of the corresponding technical solutions from the scope of the embodiments of the present disclosure.

1. A quantum dot light-emitting device, comprising: an anode, a cathode, and a light-emitting layer disposed between the anode and the cathode,
wherein the light-emitting layer comprises a first quantum dot light-emitting layer to an Nth quantum dot light-emitting layer sequentially arranged in a direction from the anode to the cathode, N is an integer greater than or equal to 2, the first quantum dot light-emitting layer comprises a first core-shell quantum dot, the Nth quantum dot light-emitting layer comprises an Nth core-shell quantum dot, each core-shell quantum dot comprises a core and at least one shell layer coated on a surface of the core, and thicknesses of respective outermost shell layers of the first core-shell quantum dot to the Nth core-shell quantum dot become sequentially increased.

2. The quantum dot light-emitting device according to claim 1, wherein
one or more of the first core-shell quantum dot to the Nth core-shell quantum dot are of a multi-shell layer structure, respectively, and an energy level width of an outermost shell layer of the multi-shell layer structure is greater than an energy level width of the core.

3. The quantum dot light-emitting device according to claim 1, wherein the light-emitting layer is composed of the first quantum dot light-emitting layer and a second quantum dot light-emitting layer, the first quantum dot light-emitting layer comprises the first core-shell quantum dot, the second quantum dot light-emitting layer comprises a second core-shell quantum dot, a thickness of an outermost shell layer of the second core-shell quantum dot is greater than that of the first core-shell quantum dot, and energy level widths of the outermost shell layers of the first core-shell quantum dot and the second core-shell quantum dot are greater than an energy level width of the core, respectively.

4. The quantum dot light-emitting device according to claim 1, wherein the light-emitting layer is composed of the first quantum dot light-emitting layer, a second quantum dot light-emitting layer, and a third quantum dot light-emitting layer, the first quantum dot light-emitting layer comprises the first core-shell quantum dot, the second quantum dot light-emitting layer comprises a second core-shell quantum dot, the third quantum dot light-emitting layer comprises a third core-shell quantum dot, the thicknesses of the respective outermost shell layers of the first core-shell quantum dot to the third core-shell quantum dot become sequentially increased, and energy level widths of the outermost shell layers of the first core-shell quantum dot, the second core-shell quantum dot, and the third core-shell quantum dot are greater than an energy level width of the core, respectively.

5. The quantum dot light-emitting device according to claim 1, wherein the first core-shell quantum dot to the Nth core-shell quantum dot are a type I quantum dot.

6. The quantum dot light-emitting device according to claim 1, wherein emission peak wavelengths of any two of the first quantum dot light-emitting layer to the Nth quantum dot light-emitting layer are same as each other, or an absolute value of a difference between emission peak wavelengths of any two of the first quantum dot light-emitting layer to the Nth quantum dot light-emitting layer is less than 1 nm.

7. The quantum dot light-emitting device according to claim 1, wherein one or more of the first core-shell quantum dot to the Nth core-shell quantum dot have two shell layers, three shell layers, or four shell layers, respectively.

8. The quantum dot light-emitting device according to claim 1, wherein energy level widths of corresponding shell layers of one or more of the first core-shell quantum dot to the Nth core-shell quantum dot become sequentially widened from a center of the core-shell quantum dots outward.

9. The quantum dot light-emitting device according to claim 1, wherein shell layers, except for the outermost shell layers, of the first core-shell quantum dot to the Nth core-shell quantum dot have a same thickness distribution.

10. The quantum dot light-emitting device according to claim 1, wherein the quantum dot light-emitting device is a blue quantum dot light-emitting device or a green quantum dot light-emitting device, the first core-shell quantum dot to the Nth core-shell quantum dot each independently have three or four shell layers, the thicknesses of the respective outermost shell layers of the first core-shell quantum dot to the Nth core-shell quantum dot become sequentially increased, and thicknesses of respective secondary outer shell layers of the first core-shell quantum dot to the Nth core-shell quantum dot become sequentially increased.

11. The quantum dot light-emitting device according to claim 1, wherein the quantum dot light-emitting device is a red quantum dot light-emitting device, the first core-shell quantum dot to the Nth core-shell quantum dot each independently have three or four shell layers, and all shell layers of the first core-shell quantum dot to the Nth core-shell quantum dot become sequentially increased.

12. The quantum dot light-emitting device according to claim 1, wherein cores of the first core-shell quantum dot to the Nth core-shell quantum dot are each independently selected from one or more of CdSe, CdS, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, CdZnSTe, CdSeSTe, ZnSeSTe, CdZnSeSTe, InP, InAs, InAsP, PbS, PbSe, PbTe, PbSeS, PbSeTe, or PbSTe; and
the shell layers of the first core-shell quantum dot to the Nth core-shell quantum dot are each independently selected from one or more of CdSe, CdS, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, CdZnSTe, CdSeSTe, ZnSeSTe, CdZnSeSTe, InP, InAs, InAsP, PbS, PbSe, PbTe, PbSeS, PbSeTe, or PbSTe.

13. The quantum dot light-emitting device according to claim 1, wherein one or more of the first core-shell quantum dot to the Nth core-shell quantum dot are one of a CdSe//ZnSe//ZnS quantum dot, a CdSe//CdZnSe//CdZnS quantum dot, or a InP//GaP//ZnS quantum dot.

14. The quantum dot light-emitting device according to claim 1, wherein the quantum dot light-emitting device further comprises a hole transport layer disposed between the light-emitting layer and the anode, and an electron transport layer disposed between the light-emitting layer and the cathode, preferably, the quantum dot light-emitting device further comprises a hole injection layer disposed between the anode and the hole transport layer.

15. The quantum dot light-emitting device according to claim 14, wherein a valence band energy level of the hole injection layer is higher than that of the hole transport layer, the valence band energy level of the hole transport layer is higher than that of the outermost shell layer of the first core-shell quantum dot in the adjacent first quantum dot light-emitting layer, and a valence band energy level of the electron transport layer is lower than that of the outermost shell layer of the Nth core-shell quantum dot in the adjacent Nth quantum dot light-emitting layer; and
a conduction band energy level of the hole injection layer is lower than that of the hole transport layer, the conduction band energy level of the hole transport layer is higher than that of the outermost shell layer of the first core-shell quantum dot in the adjacent first quantum dot light-emitting layer, and a conduction band energy level of the electron transport layer is lower than that of the outermost shell layer of the Nth core-shell quantum dot in the adjacent Nth quantum dot light-emitting layer.

16. The quantum dot light-emitting device according to claim 14, wherein a material of the hole transport layer is selected from one or more of poly(9,9-dioctylfluorene-CO—N-(4-butylphenyl)diphenylamine), poly(3-hexylthiophene), poly(9-vinylcarbazole), poly[bis(4-phenyl)(4-butylphenyl)amine], 4,4′,4′-tris(carbazol-9-yl)triphenylamine, 4,4′-bis(9-carbazol)biphenyl;
a material of the electron transport layer is selected from a N-type nano-metal oxide, and the N-type nano-metal oxide is selected from one or more of zinc oxide, titanium dioxide, magnesium oxide, aluminum oxide, or oxides of alloys of the metals;
a material of the hole injection layer is selected from one or more of poly(3,4-ethylenedioxythiophene)-poly(styrene sulfonate), 4,4′,4″-tris(N-3-methylphenyl-N-phenylamino)triphenylamine, 4,4′,4″-tris[2-naphthylphenylamino]triphenylamine, 2,3,6,7,10,11-hexacyano-1,4,5,8,9,12-hexaazatriphenylene, 2,3,5,6-tetrafluoro-7,7′,8,8′-tetracyanodimethyl-p-benzoquinone, molybdenum trioxide;
a material of the anode is selected from ITO or FTO, and a material of the cathode is selected from one or more of aluminum, magnesium, calcium, silver or alloys thereof.

17. A display apparatus, comprising a quantum dot light-emitting device, wherein the quantum dot light-emitting device comprises: an anode, a cathode, and a light-emitting layer disposed between the anode and the cathode, and
the light-emitting layer comprises a first quantum dot light-emitting layer to an Nth quantum dot light-emitting layer sequentially arranged in a direction from the anode to the cathode, N is an integer greater than or equal to 2, the first quantum dot light-emitting layer comprises a first core-shell quantum dot, the Nth quantum dot light-emitting layer comprises an Nth core-shell quantum dot, each core-shell quantum dot comprises a core and at least one shell layer coated on a surface of the core, and thicknesses of respective outermost shell layers of the first core-shell quantum dot to the Nth core-shell quantum dot become sequentially increased.

18. A method of manufacturing a quantum dot light-emitting device, comprising the following steps of:
S1. providing a cathode or an anode;
S2. preparing a light-emitting layer on the cathode or the anode, wherein the light-emitting layer comprises at least two quantum dot light-emitting layers, each of the quantum dot light-emitting layers comprises a core-shell quantum dot, the core-shell quantum dot comprises a core and at least one shell layer coated on a surface of the core, and thicknesses of respective outermost shell layers of the core-shell quantum dots of the quantum dot light-emitting layers become sequentially increased in a direction from the anode to the cathode; and
S3. preparing the anode or the cathode on the light-emitting layer.

19. The method according to claim 18, further comprising: preparing a hole transport layer between the light-emitting layer and the anode, and preparing an electron transport layer between the light-emitting layer and the cathode.

20. The method according to claim 19, further comprising: preparing a hole injection layer between the anode and the hole transport layer.
